(19) United States
(12) Patent Application Publication
(10) Pub. No.: US 2024/0244806 A1
(43) Pub. Date: Jul. 18, 2024

(54) POWER ELECTRONIC ARRANGEMENT FOR AN EXTERNALLY EXCITED SYNCHRONOUS MACHINE, MOTOR VEHICLE AND METHOD FOR PRODUCING A POWER ELECTRONIC ARRANGEMENT

(71) Applicant: AUDI AG, Ingolstadt (DE)

(72) Inventor: Daniel RUPPERT, Lenting (DE)

(21) Appl. No.: 18/414,194

(22) Filed: Jan. 16, 2024

(30) Foreign Application Priority Data
Jan. 17, 2023 (DE) 102023100938.9

(51) Int. Cl. H05K 7/20; H02K 19/36; H02K 19/38; H02M 7/00

(52) U.S. Cl. CPC H05K 7/20927; H02K 19/36; H02K 19/38; H02M 7/003

(57) ABSTRACT

A power electronic arrangement for an externally excited synchronous machine is disclosed and may comprise a heat sink, at least one inverter power module including an inverter and at least one exciter power module including an exciter circuit. The at least one inverter power module may be mounted in a predefined relative inverter position and orientation on the heat sink by material bonding The heat sink and the exciter power module may each include positioning devices configured to interlock such that a desired relative exciter power module position and orientation relative to the inverter power modules is produced by interlocking the positioning devices of the heat sink and the exciter power module.

### BACKGROUND

### Technical Field

The present disclosure relates to a power electronic arrangement for an externally excited synchronous machine, a motor vehicle having such a power electronic arrangement and a method of producing such a power electronic arrangement.

### Description of the Related Art

Externally excited synchronous machines may be used as a drive machine (traction machine) in an electrified motor vehicle. In contrast with a permanently excited synchronous machine, where the magnetic field of the rotor may be provided by permanent magnets, an externally excited synchronous machine (EESM) may include an exciter winding in the rotor, which is energized via an exciter circuit, which may be provided in an exciter power module. Moreover, an inverter may be associated with an externally excited synchronous machine, configured to convert between a DC voltage, such as that of a high-voltage network of a motor vehicle, and the multiphase alternating voltage of the stator windings. In order to realize the inverter, an inverter power module may be provided for each phase of a power electronic arrangement associated with the externally excited synchronous machine. Three-phase externally excited synchronous machines may be used. Hence, an associated power electronic arrangement provided for such externally excited synchronous machines may comprise three inverter power modules for the three phases as well as an exciter power module to provide the exciter circuit.

The power modules discussed herein, i.e., inverter power modules and exciter power modules, comprise power semiconductor components, such as semiconductor switches and/or diodes, and the power modules require cooling due to the heat produced by the power semiconductor components. It is known to provide a common heat sink for the power electronic modules. For active cooling, the heat sink may have an internal cavity, for example, through which a coolant flows. For example, DE102019128721A1 discloses a power electronic device for an externally excited synchronous machine in which inverter modules realized as individual components and an exciter module realized as a component are thermally connected to a common cooling device.

In many instances, the construction and connection techniques of the power modules of the inverter differ from the power module constituting the exciter circuit, due to power or cost aspects. For example, an exciter power module may be realized as a frame module, including a gel casting compound, while the power semiconductors may be realized in silicon. In contrast, the three inverter power modules may be designed as molded half-bridge modules, such that no gel casting is needed because of the mold casting compound, which solidifies to provide the shape. The power semiconductor components for inverter power modules are often designed in silicon carbide technology. The inverter power modules in this context are often mounted by material bonding on the heat sink, such as being soldered or sintered, while the exciter power module may be mounted by force locking, such as through a screw connection as the fastening device or means. A thermal connection material may also be used between the exciter power module and the heat sink.

If the different power module technologies described above are placed on a common heat sink, differences may result in the accuracy of their mounting. For example, if both the inverter power modules and the exciter power module include contacting pins for connection to a circuit board, which may carry a control unit of the power electronic arrangement for example, it is known in the prior art how to provide different circuit boards for the connection to the exciter power module and to the inverter power modules, respectively. Such contacting pins may extend from the power modules on the side facing away from the heat sink, i.e., the fastening side.

Alternatively, a ‘single circuit board design’ may be desirable, because the components of the control device may be realized on a common circuit board and only one circuit board may be needed. However, due to the different power module technologies, there may be high demands on the tolerances of the contacting pins. Therefore, two separate circuit boards are commonly used in the prior art, which may result in increased material costs for two separate circuit boards and plug connectors between the circuit boards, increased production costs and development costs for the circuit boards, increased expenses in the fabrication, and less robustness or greater fault vulnerability. The design with two circuit boards is poorly suited to a highly automated large series production, as a press-fit process is only possible with one circuit board.

DE102020211423A1 discloses a method for production of an inverter, a positioning aid, and an inverter. The method includes positioning and orienting at least one half-bridge module on a heat sink, making use of a positioning aid. The positioning aid is fashioned as a frame and encloses the at least one half-bridge module such that the at least one half-bridge module is forced by the positioning aid to adopt a given position and orientation. The positioning aid is connected to the heat sink in a predetermined position and orientation. A form-fitting grasping of the half-bridge module is thus provided.

### BRIEF SUMMARY

The present disclosure provides a configuration of a power electronic arrangement for an externally excited synchronous machine with a single circuit board design, whereby power modules can be mounted on a heat sink in different fastening technologies.

The heat sink and the exciter power module may have interlocking positioning devices or means such that a desired relative exciter power module position and orientation relative to the inverter power modules may be produced by the interlocking.

Thus, according to the present disclosure, a plurality of power modules, such as an exciter power module and at least one inverter power module, may be mounted on a heat sink and thermally connected thereto. The heat sink, which may consist of aluminum, may include a cavity through which a coolant, such as cooling water, may flow for active cooling. In some embodiments, one inverter power module may be provided for each phase. In a three-phase configuration, three inverter power modules may be provided, which may be configured as molded half-bridge modules. In some embodiments, the plurality of inverter power modules may be mounted directly next to each other in succession at a middle portion of the oblong heat sink in the longitudinal direction and may be thermally connected. The exciter power module may then be mounted and thermally connected in the longitudinal direction.

In a manufacturing process according to the present disclosure, the three inverter power modules may be connected by material bonding to the heat sink, for example, by soldering and/or sintering. In this mounting process and thermal connection process, the three inverter power modules may be placed sufficiently accurately on the heat sink and relative to each other, such that only slight tolerances will result relative to inverter position and orientation. The exciter power module, however, may then be mounted on the heat sink and thermally connected thereto by force locking. For example, a thermal connection material, such as a thermal paste, may be applied to the heat sink and then the exciter power module may be mounted with force locking by a fastening device or means. The power electronic arrangement may comprise a screw connection for the mounting of the exciter power module for the force-locking connection. For example, the exciter power module may be mounted by a screw connection. When using a thermal connection material between the exciter power module and the heat sink a layer of the thermal connection material may be formed which significantly improves the heat conduction between the exciter power module and the heat sink regardless of the specific force-locking mount device.

However, larger tolerances may occur in the force-locking mounting of the exciter power module, such as during the screw connection. For example, a slightly twisted mounting of the exciter module may occur, due to use of a central screw and/or when the threaded holes for the screws are provided in the heat sink. In such embodiments, the permitted tolerances for a connection of the contacting pins to a common circuit board may no longer be satisfied.

In order to enable a single circuit board design of the power electronic arrangement, such that the circuit board extends across all the power modules, the exciter power module, which is the last power module to be mounted, must be placed with sufficient accuracy such that it conforms to the tolerances of the contacting pins of all the power modules. The present disclosure thus provides a positioning device or means on the heat sink and on the exciter power module, which may be configured to interact with each other, such as by interlocking, enabling the correct, precise, and permitted tolerance obeying positioning of the exciter power module in the desired relative exciter power module position and orientation. For example, the positioning device or means may be configured as centering aids. Due to the positioning device or means, the exciter power module may be placed in the desired relative exciter power module position and orientation relative to the inverter power modules (and the heat sink) during the mounting process. The exciter power module may then be fastened by force locking in the exciter power module position and orientation so adopted, such as by screwing. The contacting pins of the exciter power module and those of the at least one inverter power module will thus lie within the permitted tolerances in order to then connect a single circuit board to the contacting pins of all the power electronic modules.

The positioning device or means enables a single circuit board design, despite different construction and connection techniques of the power modules, i.e., despite the fastening of the exciter power module by screwing and the fastening of the inverter power modules by soldering and/or sintering. Such a configuration enables distinct advantages in the production and in terms of production costs. In particular, a highly automated realization becomes possible.

In some embodiments, the exciter power module and the at least one inverter power module may comprise contacting pins protruding into a common contacting plane in one direction, such as facing away from the heat sink, and contacting a common circuit board. The circuit board may carry at least a portion of a control device of the power electronic arrangement, which control both the actuating of the inverter and the actuating of the exciter circuit. The contacting pins may therefore be control terminals, while the power modules may also have other connection contacts, such as connection tabs, for the electrical power connections. Such connection contacts may be provided on the side situated opposite the contacting pins with respect to the heat sink, such as the side extending in the longitudinal direction in the case of an elongated heat sink. The connection contacts for the exciter power module may be formed on the same side as the contacting pins.

In some embodiments, the contacting pins may be connected to the circuit board by press-in techniques. Press-in techniques (i.e., press-fit technology) refers to solder-free connection techniques in which a contacting pin (i.e., contact pin) is pressed into a metallized through hole of a circuit board. During the production of the power electronic arrangement, the circuit board may be pressed on, producing the connection of the contacting pins to the circuit board by press-in techniques.

The present disclosure provides a configuration in which both the relative positioning in terms of height of the power modules and the contacting pins are adapted to each other, such that a single circuit board can subtend the contacting plane in which the contacting pins protrude. Thus, the material costs may be reduced by the use of a single circuit board, as no plug connectors between circuit boards are needed. The production costs may also be reduced, as only a single circuit board needs to be produced, mounted with components, and tested. The expenses may also be reduced in the fabrication, as now only one circuit board needs to be mounted. The development costs may be lower, as only one circuit board needs to be developed. Finally, the robustness of the power electronic arrangement may be enhanced, as additional plug connectors and cables between multiple circuit boards may be avoided.

The positioning device or means ensures the exciter power module is positioned and oriented correctly, such that manual insertion and tightening of the screw of the exciter power module may be avoided in favor of automation. Such a configuration enables a highly automated large series production, which may include use of a press-in technique for the connection to the circuit board. Only a single pressing process may be necessary for the circuit board in the mounting of the power electronic arrangement in order to connect and fasten the circuit board to the contacting pins of all the power modules.

The contacting pins of the inverter power modules may provide control terminals. For example, the inverter power modules, which may be configured to handle large and variable amounts of power, may additionally have other connection contacts, such as connection tabs for the inverter power, which may extend from the side. For the exciter power module, however, the contacting pins may have both control terminals and exciter power terminals. Regardless of whether the contacting pins of the exciter power module provide only control terminals or also exciter power terminals, the common circuit board may be a control circuit board for the power modules. For example, the control terminals may control the making and breaking processes of semiconductor switches as the power semiconductor components of the power modules.

The power modules may be coupled to the heat sink by a fastening side and the contacting pins may extend from the side situated opposite the fastening side. The power modules may be situated (i.e., sandwiched) between the common circuit board and the common heat sink. The circuit board may be arranged at a certain distance from the top side of the power modules due to the resulting heat.

A method according to the present disclosure for producing a power electronic arrangement for an externally excited synchronous machine as described herein may include the following steps:
providing a heat sink;
mounting, by material bonding, at least one inverter power module providing an inverter in a predefined relative inverter position and orientation on the heat sink; and
mounting an exciter power module, comprising an exciter circuit, by way of a fastening device or means making use of interlocking positioning device or means of the heat sink and the exciter power module, on the heat sink, such that the interlocking of the positioning device or means produces a desired relative exciter power module position and orientation relative to the inverter power modules.

The embodiments of the power electronic arrangement described herein may be applied analogously to the method for production of the power electronic arrangement.

In some embodiments, in a first step, the inverter power modules may be mounted with material bonding by soldering and/or sintering. The permitted tolerances of a predefined relative inverter position and orientation on the heat sink may be satisfied by such techniques. In a second step, the inverter power module may then be mounted on the heat sink, such as by force locking and may then be thermally connected thereto. Since rather large uncertainties may arise due to a Force-locking, such as with a screw connection, may enable large uncertainties, so the positioning device or means may be used to interlock the desired relative exciter power module position and orientation relative to the inverter power modules within the permitted tolerances by automatically positioning and orienting the exciter power module.

The exciter power module and the at least one inverter power module may comprise contacting pins protruding into a common contacting plane in one direction, such as the direction facing away from the heat sink, and, after the mounting of the exciter power module, all of the contacting pins may be connected to a common circuit board. The circuit board may be pressed thereon, and the connection of the contacting pins to the circuit board may be produced by press-in techniques.

The positioning device or means may comprise at least one pair, of a protrusion and a recess configured such that the protrusion engages in a precise fit. In some embodiments, one pair of a protrusion and a recess is sufficient, such that the protrusion and the recess enable an interlocking in only one clearly defined orientation corresponding to the desired exciter power module orientation. In some embodiments, at least three, preferably four, pairs of a protrusion and a recess with which the protrusion engages in an exact fit may be used.

The protrusion and the recess may each have a conical or pyramidally tapering guide surface, such that the protrusion and the recess are configured to bear against each other during a positioning process. The protrusions may have a conical segment and/or a pyramidal segment. For example, at least substantially truncated cones may be used as the protrusions. The protrusions may be referred to as a ‘positioning cone’. In embodiments including multiple pairs, the protrusions may be provided on both the heat sink and on the exciter power module. The protrusions may be provided on the fastening side of the exciter power module, such that the protrusions may be produced by injection molding, for example, by providing recesses in the corresponding casting mold. The respective mating pieces of the pair, i.e., the recesses, may then be provided in the heat sink. The exciter power module may be placed in its desired exciter power module position and orientation along the guide surfaces making contact with each other during the mounting process.

The present disclosure also relates to a motor vehicle, comprising an externally excited synchronous machine designed as a traction machine and a power electronic arrangement according to the present disclosure associated with the synchronous machine. All the benefits and features regarding the power electronic arrangement according to the disclosure and the method according to the disclosure may be applied analogously to the motor vehicle according to the disclosure, with which therefore the already mentioned benefits can be obtained.

### BRIEF DESCRIPTION OF THE SEVERAL VIEWS OF THE DRAWINGS

FIG. 1 shows a power electronic arrangement without the circuit board.

FIG. 2 shows a partial, schematic cross-sectional view of the power electronic arrangement.

FIG. 3 shows an exciter power module.

FIG. 4 shows a schematic of a motor vehicle.

### DETAILED DESCRIPTION

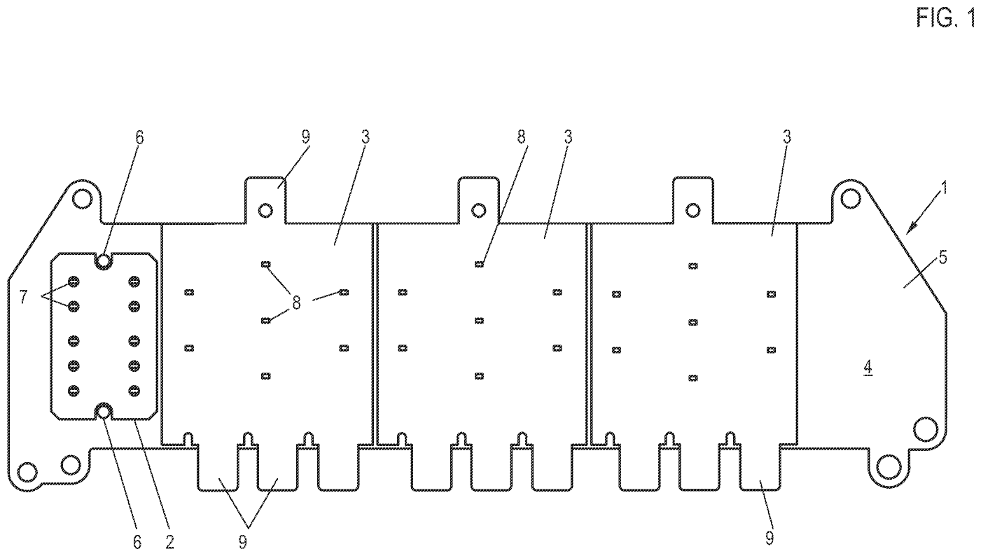

FIG. 1 shows a schematic view of a power electronic arrangement 1 according to the present disclosure, in which the common circuit board for an exciter power module 2 and the inverter power modules 3 is not shown for clarity. The power electronic arrangement 1 may be associated with an externally excited synchronous machine. The power electronic modules 3 may provide half-bridges for each of the phases of the power electronic arrangement 1 (three phases in FIG. 1) and the exciter power module may provide an exciter circuit to the power electronic arrangement 1, which may also be formed as a bridge circuit. The power electronic modules 2, 3 may be mounted on a top side 4 of a heat sink 5 and may be thermally connected thereto. Both the exciter power module 2 and the inverter power modules 3 may comprise power semiconductor components, including semiconductor switches and diodes (not shown in FIG. 1).

The exciter power module 2 and the inverter power modules 3 may differ in their connection to the heat sink 5. The exciter power module 2 may be mounted by way of a screw connection 6 with force locking on the heat sink 5 and may be thermally coupled by a thermal connection material. The inverter power modules 3, which may be provided as molded half-bridge modules, may be mounted by sintering and/or soldering on the heat sink 5 near a cavity of the heat sink 5 through which a coolant flows and is thermally connected thereto. The exciter power module 2 may be situated in the region of an inlet opening for the coolant, which may be cooling water.

As can be seen in FIG. 1, the exciter power module 2 may include contacting pins 7 on its top side, extending therefrom, opposite the fastening side on the heat sink 5. The contacting pins 7 may include at least control terminals. The contacting pins 7 may also comprise exciter power terminals, but the exciter power terminals may be provided elsewhere as an alternative.

The inverter power modules 3 may include contacting pins 8 as control terminals extending from the top side of the inverter power modules 3 facing away from the heat sink 5. The inverter power terminals (connection contacts) 9 may be provided in the form of tabs on the sides of the elongated heat sink 5. The inverter power modules 3 may be mounted in succession and next to each other on the inverter power terminals 9 at the center in the longitudinal direction.

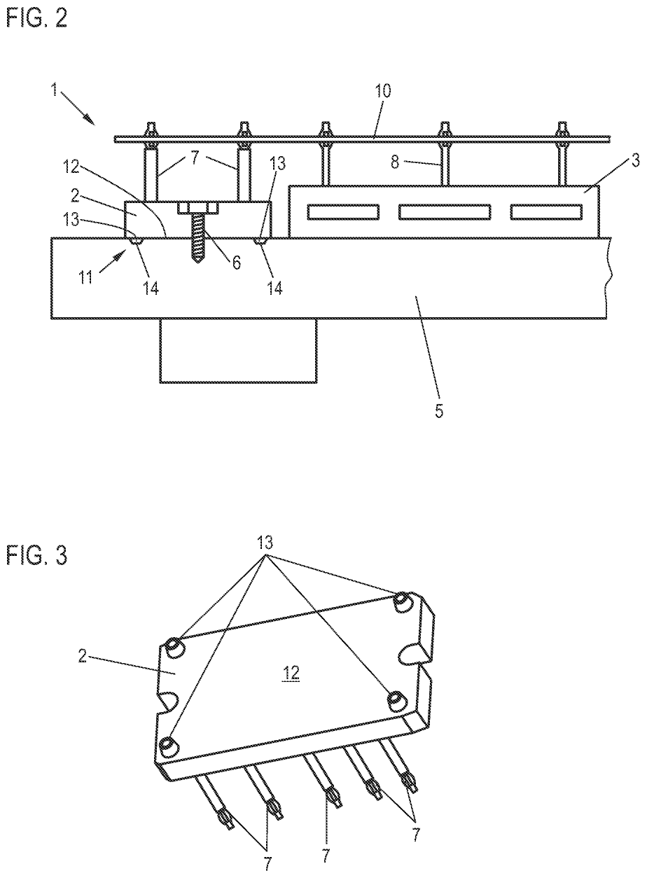

As can be seen in the schematic cross-sectional view of FIG. 2, the contacting pins 7 and the contacting pins 8 may be configured to protrude as far as a common contacting plane, in which a common circuit board 10 may be situated. The contacting pins 7, 8 may be coupled by press-in techniques (i.e., press-fit technology) to the circuit board by pressing on the board in a single pressing step, such that the contacting pins 7, 8 may be pressed through respective through holes in the circuit board 10. Contacting may be enabled due to the central recess in the top region.

In order to make use of press-in techniques, the contacting pins 7, 8 must be situated at the positions at which the contacting pins 7, 8 are to be connected, within permitted tolerances. When the inverter power modules 3 are mounted by soldering or sintering with material bonding on the heat sink 5 such that the predefined, desired inverter position and inverter orientation on the heat sink 5 and relative to the other inverter power modules 3 may be produced with high accuracy and larger tolerances may be enabled for the screw connection 6, which may exceed the permitted tolerances for the use of a common circuit board 10 and the press-in techniques. Positioning means 11 may be provided, which may be configured to correctly position and orient the exciter power module 2 automatically by interlocking during the mounting process, enabling a precise production of the desired relative exciter power module position and exciter power module orientation relative to the inverter power modules 3. The positioning means 11 may comprise protrusions 13 extending from the fastening side 12 of the exciter power module 2, i.e., toward the heat sink 5. The protrusions 13 may be formed as truncated cones, and may have a conically tapering guide surface. Each protrusion 13 may form a corresponding pair with a recess 14 of the heat sink 5, such that the protrusion 13 may engage with the recess 14. The recess 14 may include a conically tapering guide surface, which may be configured to correspond to the conically tapering guide surface of the protrusion 13 and which may be configured to contact the conically tapering guide surface of the protrusion 13 during the positioning process. The positioning means 11 may enable the exciter power module 2 to be properly positioned and oriented during the mounting process, such that the exciter power module 2 may then be fastened in place.

FIG. 3 shows a perspective view of the exciter power module 2, in an embodiment in which the exciter power module 2 comprises four protrusions 13, one at each corner of the generally rectangular base shape of the fastening surface 12. The contacting pins 7 may extend from the oppositely situated side.

During the method of producing the power electronic arrangement 1, after providing the heat sink 5, the inverter power modules 3 may be mounted by material bonding with high precision in the predefined relative inverter position and inverter orientation on the heat sink 5. Next, the exciter power module 2 may be positioned on the heat sink 5 by way of the interlocking positioning means 11 of the heat sink 5 (i.e., the recesses 14) and the exciter power module 2 (i.e., the protrusions 13) in a desired relative exciter power module position and exciter power module orientation relative to the inverter power modules 3. The exciter power module 2 and the heat sink 5 may be secured by way of the fastening device or means, such as the screw connection 6. Next, the circuit board 10 may be pressed on. The contacting pins 7, 8 may be connected using press-in techniques (i.e., press-fit technology).

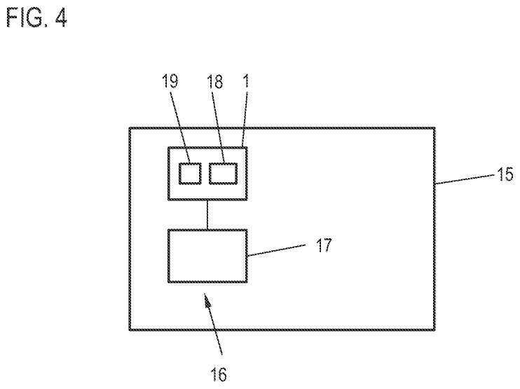

FIG. 4 shows a schematic of a motor vehicle 15 according to the present disclosure. The motor vehicle 15 may be an electric motor vehicle using an externally excited synchronous machine 17 as a traction machine 16. The externally excited synchronous machine 17 may be associated with a power electronic arrangement 1 according to the present disclosure, includes provides an inverter 18 and an exciter circuit 19. The exciter circuit 19 may be coupled to an exciter winding of the synchronous machine 17 and the inverter 18 may be coupled to stator windings.

German patent application no. 10 2023 100938.9, filed Jan. 17, 2023, to which this application claims priority, is hereby incorporated herein by reference, in its entirety.

Aspects of the various embodiments described above can be combined to provide further embodiments. In general, in the following claims, the terms used should not be construed to limit the claims to the specific embodiments disclosed in the specification and the claims, but should be construed to include all possible embodiments along with the full scope of equivalents to which such claims are entitled.

1. A power electronic arrangement for an externally excited synchronous machine, comprising:
a heat sink;
at least one inverter power module including an inverter; and
at least one exciter power module including an exciter circuit,
wherein the at least one inverter power module is mounted in a predefined relative inverter position and orientation on the heat sink by material bonding, and
wherein the heat sink and the exciter power module each include positioning devices configured to interlock such that a desired relative exciter power module position and orientation relative to the inverter power modules is produced by interlocking the positioning devices of the heat sink and the exciter power module.

2. The power electronic arrangement according to claim 1, wherein the at least one exciter power module and the at least one inverter power module each include contacting pins protruding into a common contacting plane in one direction, and
wherein the contacting pins of the at least one exciter power module and the at least one inverter power module are configured to contact a common circuit board.

3. The power electronic arrangement according to claim 2, wherein the contacting pins are connected to the common circuit board by press-in techniques.

4. The power electronic arrangement according to claim 2, wherein the contacting pins of the at least one exciter power module and the at least one inverter power module extend away from the heat sink.

5. The power electronic arrangement according to claim 1, wherein the at least one inverter power module is mounted by material bonding through at least one of soldering and/or sintering.

6. The power electronic arrangement according to claim 5, wherein a thermal connection material is provided between the at least one exciter power module and the heat sink.

7. The power electronic arrangement according to claim 6, wherein the thermal connection material comprises a thermal paste.

8. The power electronic arrangement according to claim 1, wherein the exciter power module is mounted by a screw connection.

9. The power electronic arrangement according to claim 1, wherein the positioning devices include at least one positioning pair, each pair of the at least one positioning pair including a protrusion and a recess, and wherein the protrusion and the recess are each configured such that the protrusion engages in a precise fit with the recess when interlocked.

10. The power electronic arrangement according to claim 9, wherein the protrusion and the recess each include a conical or pyramidally tapering guide surface, the tapering guide surfaces being configured to bear against each other during a positioning process.

11. The power electronic arrangement according to claim 9, wherein the positioning devices include at least three positioning pairs.

12. A method for producing a power electronic arrangement for an externally excited synchronous machine, comprising:
mounting at least one inverter power module including an inverter in a predefined relative inverter position and orientation on a heat sink by material bonding; and
mounting an exciter power module including an exciter circuit on the heat sink by way of a fastening device and by interlocking positioning devices of the heat sink and the exciter power module, wherein the interlocking of the positioning devices produces a desired relative exciter power module position and orientation relative to the inverter power modules.

13. The method according to claim 12, further comprising:
connecting contacting pins of the exciter power module and the at least one inverter power module to a common circuit board after the mounting of the exciter power module,
wherein the contacting pins protrude into a common contacting plane in a first direction.

14. The method according to claim 13, further comprising:
pressing the common circuit board onto the contacting pins by press-in techniques, such that the contacting pins are connected to the common circuit board.

15. The method according to claim 13, wherein the contacting pins face away from the heat sink.

16. The method according to claim 12, wherein mounting the at least one inverter power module includes at least one of soldering and sintering.

17. The method according to claim 16, further comprising:
applying a thermal connection material to the heat sink, such that the exciter power module is arranged on the thermal connection material.

18. The method according to claim 17, wherein the thermal connection material comprises a thermal paste.

19. The method according to claim 12, wherein the fastening device includes a screw connection.

20. A motor vehicle, comprising an externally excited synchronous machine as a drive machine thereof and a power electronic arrangement, the power electronic arrangement comprising:
a heat sink;
at least one inverter power module including an inverter; and
at least one exciter power module including an exciter circuit,
wherein the at least one inverter power module is mounted in a predefined relative inverter position and orientation on the heat sink by material bonding, and
wherein the heat sink and the exciter power module each include positioning devices configured to interlock such that a desired relative exciter power module position and orientation relative to the inverter power modules is produced by interlocking the positioning devices of the heat sink and the exciter power module.
